(19) United States
(12) Patent Application Publication
(10) Pub. No.: US 2025/0266376 A1
(43) Pub. Date: Aug. 21, 2025

(54) Semiconductor Component Including One or More Conductors Comprising a Stack of Ferromagnetic and Nonmagnetic Materials

(71) Applicant: IMEC VZW, Leuven (BE)

(72) Inventors: Xiao Sun, Wilsele (BE); Martijn Huynen, Sint-Amandsberg (BE); Eric Beyne, Heverlee (BE)

(21) Appl. No.: 19/057,432

(22) Filed: Feb. 19, 2025

(30) Foreign Application Priority Data
Feb. 21, 2024 (EP) 24158776.5

(51) Int. Cl. H01L 23/66; H01L 21/768; H01L 23/498; H01L 23/538

(52) U.S. Cl. CPC H01L 23/66; H01L 21/76877; H01L 23/49872; H01L 23/5383

(57) ABSTRACT

An example embodiment includes a semiconductor component. The semiconductor component includes a semiconductor substrate and at least one layer of dielectric material. The layer has a planar upper surface. An electrical conductor is arranged in a first trench and formed in the layer of dielectric material. The first trench includes a base and a pair of upstanding sidewalls. The conductor includes a stack of alternate ferromagnetic and non-magnetic layers. The stack extends along the base and the sidewalls of the first trench so that the stack defines a second trench inside the first trench. The conductor also includes an electrically conductive portion that integrally fills the second trench.

### CROSS-REFERENCE TO RELATED APPLICATIONS

The present application is a non-provisional patent application claiming priority to European Patent Application No. 24158776.5, filed Feb. 21, 2024, the contents of which are hereby incorporated by reference.

### TECHNICAL FIELD

The present disclosure is related to semiconductor processing, in particular to the production of interconnect lines suitable for high frequency signal transfer.

### BACKGROUND

New standards are being developed for signal transfer in semiconductor chips and in particular between chips in 2.5D and 3D architectures. For example, the UCIe (Universal Chiplet Interconnect Express) specification addresses interconnects between small integrated circuit chips, also referred to as chiplets. Instead of making one large chip with all functionalities disposed on it, UCIe interconnects different chiplets into broader packages. To minimize the explosion in the number of interconnect lines between chiplets, interconnects need to move to higher frequencies such as 38 gigabits per second per interconnect line.

Traditional conductors such as copper wires however suffer from increased resistive loss at these high frequencies as a consequence of the skin effect: current travels through a thin outer layer of the conductor and not through the bulk, which increases the resistance significantly. One proposed solution to the skin effect is to produce multilayered conductors formed of alternating layers of ferromagnetic material and non-magnetic material. These so-called metaconductors have been studied in lab conditions where stacks of the alternating layers were produced by the lift-off process.

One approach for producing such metaconductors involves damascene-type processing methods, wherein consecutive ferromagnetic and non-magnetic layers are deposited in a trench. In order to mimic the layer structure obtained by the lift-off process, the material formed on the sidewalls of the trench is removed, resulting in a metaconductor formed of parallel planar layers stacked in the trench. The removal of the sidewall-deposited material however complicates the process significantly.

### SUMMARY

The present disclosure is related to a semiconductor component, a semiconductor package, and to a method as disclosed in the appended claims. In a component according to the invention, for example an integrated circuit chip or an interposer chip, a dielectric layer is provided having a planar upper surface and a first trench formed through the upper surface, the trench having a base and upstanding sidewalls. The base can also be referred to as the floor of the trench. A conductor is arranged in the trench and thereby embedded in the dielectric layer, the conductor comprising a stack formed of alternately stacked ferromagnetic and non-magnetic layers. The stack conformally follows the base and sidewalls of the trench. In other words, the stack extends along the base and sidewalls, so that the stack itself defines an inner trench, i.e. a second trench inside the first trench, the second trench having a base and sidewalls which are essentially parallel to the base and sidewalls of the first trench. The second trench is filled with a central portion of electrically conductive material. The conductor thus consists of the stack of ferromagnetic and non-magnetic layers and of the central portion of conductive material. The upper surface of the conductor is coplanar with the upper surface of the dielectric layer.

This approach addresses the above-described problem in several ways. For instance, the presence of the stack of ferromagnetic and non-magnetic layers suppresses the skin effect at high frequencies. Additionally, the presence of the stack on the sidewalls of the first trench does not deteriorate the suppression of the skin effect in a largely applicable frequency range. The removal of the stack layers from the sidewalls is therefore not required during the production process of a component according to the invention. The conductors can also be produced by a damascene-type process that is compatible with current industrial processing environments.

In a first aspect, the disclosure describes a semiconductor component. The semiconductor component includes a semiconductor substrate and at least one layer of dielectric material. The layer has a planar upper surface. An electrical conductor is arranged in a first trench and formed in the layer of dielectric material. The first trench includes a base and a pair of upstanding sidewalls. The conductor includes a stack of alternate ferromagnetic and non-magnetic layers. The stack extends along the base and the sidewalls of the first trench so that the stack defines a second trench inside the first trench. The conductor also includes an electrically conductive portion that integrally fills the second trench.

In a second aspect, the disclosure describes a method for producing an electrical conductor including a stack of alternate ferromagnetic and non-magnetic layers. The method includes providing a substrate including a layer of dielectric material having a planar upper surface. The method also includes producing a first trench in the layer of dielectric material. The first trench has a base and a pair of upstanding sidewalls. The method also includes producing a stack of said alternate ferromagnetic and non-magnetic layers along the base and the sidewalls of the first trench and on the upper surface of the layer of dielectric material so that the stack defines a second trench inside the first trench. The method also includes producing a layer of electrically conductive material directly on a top layer of the stack, said layer filling the second trench. The method also includes planarizing the stack and the layer of conductive material, thereby removing the stack from the upper surface of the layer of dielectric material.

In an third aspect, the disclosure describes means for carrying out the method of the second aspect.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 is a top view of an integrated semiconductor package comprising two chiplets interconnected, in accordance with example embodiments.

FIG. 2 is a cross-section view of a number of the conductors shown in FIG. 1, in accordance with example embodiments.

FIG. 3 is a more detailed cross-section view of one of the conductors shown in FIG. 2, in accordance with example embodiments.

FIG. 4 details the layers of the multilayer stack applied in the conductors, in accordance with example embodiments.

FIGS. 5 and 6 show the structure of conductors not in accordance with the present disclosure and used in a comparative simulation study.

FIG. 7 illustrates the resistance as a function of AC frequency, for the conductors included in the comparative simulation.

FIGS. 9 to 11 illustrate consecutive steps applied in a method, in accordance with example embodiments.

FIG. 12 illustrates a further example of a conductor, in accordance with example embodiments.

### DETAILED DESCRIPTION

Example methods and systems are described herein. Any example embodiment or feature described herein is not necessarily to be construed as preferred or advantageous over other embodiments or features. The example embodiments described herein are not meant to be limiting. It will be readily understood that certain aspects of the disclosed systems and methods can be arranged and combined in a wide variety of different configurations, all of which are contemplated herein.

Furthermore, the particular arrangements shown in the figures should not be viewed as limiting. It should be understood that other embodiments might include more or less of each element shown in a given figure. In addition, some of the illustrated elements may be combined or omitted. Similarly, an example embodiment may include elements that are not illustrated in the figures. The embodiments provided are by way of example, and are not intended to be limiting. As such, the dimensions of the drawings are not necessarily to scale.

Unless specifically specified, the description of a layer being present, deposited or produced “on” another layer or substrate, includes the options of the layer being present, produced or deposited directly on, i.e. in physical contact with, the other layer or substrate, and the layer being present, produced or deposited on one or a stack of intermediate layers between the layer and the other layer or substrate.

### I. EXAMPLE SEMICONDUCTOR COMPONENTS AND PACKAGES

A conductor according to the present disclosure are applicable in a variety of contexts in terms of the type of semiconductor component and/or package into which the conductor is incorporated. By way of example only, one particular context will first be described in some detail, namely the fabrication of interconnects between chiplets on an interposer chip. However, this disclosure is not limited thereto and other applications will be mentioned later.

Also, all materials and dimensions cited in the following detailed example are not limiting the scope of the disclosure, but are provided as examples. Alternatives to these materials and dimensions will also be described later in this text.

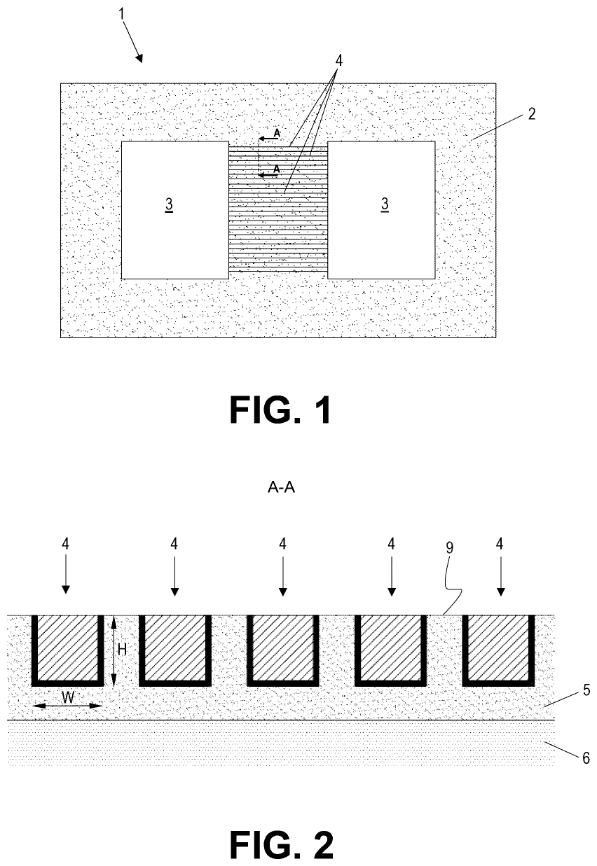

FIG. 1 depicts a top view of an integrated semiconductor package 1 including an interposer chip 2 and two chiplets 3 mounted on the interposer chip. Electrical connections between the chiplets 3 and the interposer chip 2 may be realized according to known technologies. An array of electrical conductors 4 interconnects the chiplets 3 directly. These conductors are realized in accordance with an embodiment of the invention.

FIG. 2 shows a cross-section of a number of the conductors 4. They are embedded in a layer 5 of dielectric material (hereafter also referred to as a ‘dielectric layer’) that lies on the upper surface of a semiconductor substrate portion 6 of the interposer chip 2. The dielectric layer 5 may be part of a redistribution layer of the interposer chip 2 for example. The dielectric layer 5 may be a layer of silicon oxide (SiO₂) for example.

The width (W) and height (H) of the conductors 4 as seen in the cross section is about 5 μm and the pitch of the array of conductors 4 is about 7.5 μm. The upper surface of the conductors 4 is at the same level as the planar upper surface 9 of the dielectric layer 5. In a finalized package, these upper surfaces may be covered by a further dielectric layer serving as passivation layer or sealing layer of the package.

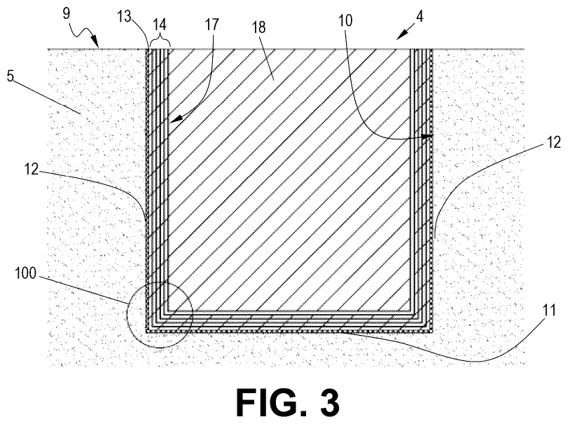

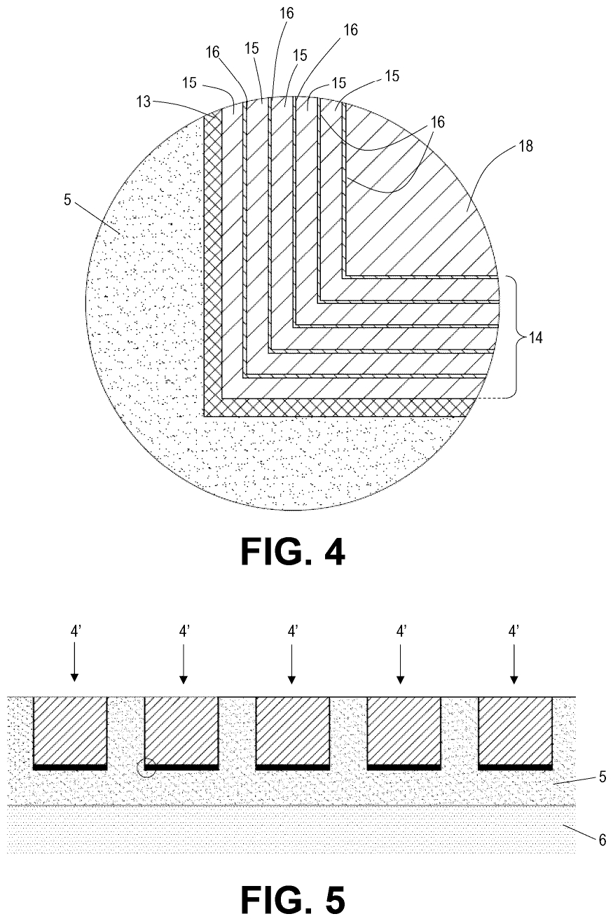

An enlarged view of the cross section of one conductor 4 is shown in FIG. 3, and a detail of a corner portion 100 of the cross section is represented in FIG. 4. As shown, the conductor 4 is arranged in a trench 10 in the dielectric layer 5. The trench 10 includes a level base 11 and upstanding sidewalls 12. The sidewalls 12 are shown to be perpendicular with respect to the base 11, but they may alternatively be slanted outwardly and mutually symmetrically with respect to the base 11.

In direct physical contact with the base 11 and the sidewalls 12 of the trench 10 is a diffusion barrier layer 13 of about 50 nm in thickness. This diffusion barrier layer 13 is required in most cases but could be omitted depending on the precise application and the choices made in terms of materials and dimensions.

Lying directly on the diffusion barrier layer 13 is a stack 14 of alternately applied non-magnetic and ferromagnetic layers, referred to hereafter as a ‘multistack’ or simply ‘stack’ 14. In the exemplary embodiment, the multistack 14 is formed of copper (Cu) layers (non-magnetic) 15 of about 60 nm in thickness, and of cobalt (Co) layers (ferromagnetic) 16 of about 10 nm thick. The total number of Cu and Co layers is 10 (5 Cu layers and 5 Co layers).

The multistack 14 extends along the base 11 and the sidewalls 12 of the trench 10 such that the stack 14 defines a second trench 17 inside the first trench 10, the second trench 17 having a base and sidewalls which are essentially parallel respectively to the base 11 and the sidewalls 12 of the first trench 10.

The remainder of the conductor 4 is formed by a bulk Cu portion 18 that integrally fills the second trench 17. The diffusion barrier layer 13 is not regarded within the present context as part of the conductor 4 (i.e. the conductor 4 consists of the multistack 14 of Cu and Co layers and of the bulk Cu portion 18). The width W and the height H of the conductor 4, as indicated in FIG. 2, therefore do not include the thickness of the diffusion barrier layer 13. The thickness of the multistack 14 in this particular example is 5×60+5×10 32 350 nm, which is about 7% of the width W (5 μm) of the conductor 4.

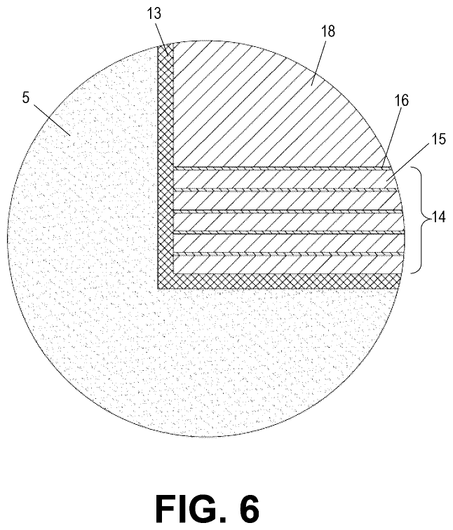

The multistack 14 of Cu and Co layers 15 and 16 is effective in suppressing the skin effect when the conductors 4 are used for conducting high frequency AC currents. The fact that the multistack 14 is formed not only on the base 11 but also on the sidewalls 12 of the trench 10 is not detrimental in terms of the skin effect suppression. This is demonstrated by a comparative simulation that compares the conductors 4 shown in FIGS. 2 to 4 with conductors 4′ illustrated in FIGS. 5 and 6, which are not in accordance with the present disclosure.

In the latter case, the multistack 14 of Cu and Co layers 15/16 having the same thicknesses as above (60 nm and 10 nm) is formed only on the base 11 of the trench 10, on top of the diffusion barrier 13, and the bulk Cu portion 18 fills the remainder of the trench 10. The diffusion barrier 13 is formed also on the sidewalls of the trench 10 in order to stop diffusion from the bulk Cu portion 15 into the dielectric layer 5.

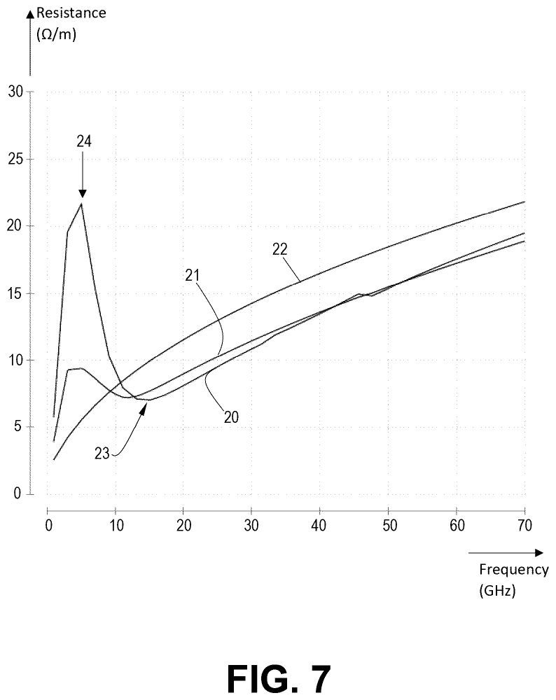

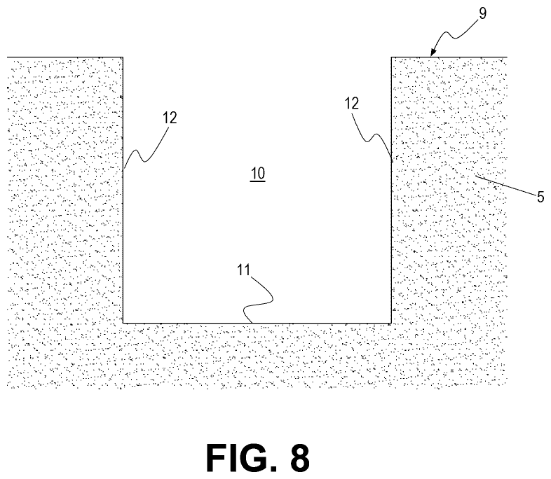

FIG. 7 compares the resistance of the conductors 4 according to the present disclosure (FIGS. 2-4) to the resistance of conductors 4′ as shown in FIGS. 5 and 6, and to conductors (not shown) formed fully of Cu. Results are obtained from a simulation of the respective conductors having dimensions and materials as described above. The full Cu conductor is a conductor fully formed of Cu and having a cross section of about 5 μm×5 μm. The curves express the resistance as a function of the frequency of the conducted current. Curve 20 represents the conductors 4 according to the invention, curve 21 represents the conductors 4′ having only a multistack on the base of the cavity 10 and curve 22 represents the full Cu conductor (no multistack).

As shown, within a wide frequency range above 10 GHz, conductors 4 and 4′ have essentially the same effectiveness in terms of suppressing the skin effect. At lower frequencies, to the left of the minimum 23, the conductor 4 according to the invention, i.e. with the multistack 14 formed on the sidewalls 12 of the trench 10, exhibits an undesirable peak 24 in the resistance. However, these frequencies are outside the applicable range for most signal transfer applications. Thus, is can be concluded that conductors in accordance with the present disclosure are effective for suppressing the skin effect at high frequencies applicable in a number of signal transfer applications, such as the signal transfer between chiplets illustrated in FIG. 1.

In some embodiments, and as is the case in the described example, all the ferromagnetic layers 16 of the multistack 14 are formed of the same ferromagnetic material and all the non-magnetic layers 15 of the stack are formed of the same non-magnetic material. In some embodiments, all the ferromagnetic layers 16 of the stack have the same thickness and all the non-magnetic layers 15 have the same thickness.

Within these latter conditions (same materials and thicknesses of the ferromagnetic and respectively the non-magnetic layers of the stack), the total number of layers in the multistack 14 and the ratio between the thicknesses of the non-magnetic layers 15 and the ferromagnetic layers 16 are parameters which are able to influence the relation between the resistance and the frequency, as represented by the curve 20 in the exemplary case described above.

For example, a higher ratio of the thickness of the non-magnetic layers 15 to the thickness of the ferromagnetic layers 16 is able to move the minimum 23 to lower frequency values. Also, for a given thickness of the non-magnetic and ferromagnetic layers of the stack, increasing the total number of layers decreases the resistance level in the applicable range (i.e. the frequency range above the minimum 23). However, this increase becomes smaller and smaller as the number of layers becomes higher. From simulations based on the above-described configuration (conductor width and height about 5 μm, Cu layers of 60 nm and Co layers of 10 nm, total of 10 layers in the multistack), it was apparent that a further increase of the number of layers above 10 does not significantly improve (i.e. additionally lower) the resistance in the frequency range of interest (above 10 GHz).

Some embodiments of the current disclosure are defined by the fact that the thickness of the multistack 14 is low compared to the total width W of the conductor as measured in a plane defined by the upper surface 9 of the dielectric layer 5 (the latter definition of W is applicable regardless of whether the sidewalls 12 of the trench 10 are perpendicular to the base 11 or slanted outwardly). According to various embodiments, the thickness of the multistack 14 is less than 30%, less than 20% or less than 10% of the width W as defined above.

In practice, embodiments where the thickness of the multistack 14 is thin compared to the width of the conductor are primarily applicable to conductors having a width and height in the order of several micrometres, and where the thickness of the layers of the multistack is in the order of nanometres, for example between 5 and 100 nm, as in the above-described example. These embodiments are advantageous compared to existing configurations because the removal of the multistack layers from the sidewalls 12 of the trench 10 is not required, and only a limited number of multistack layers, for example not more than 10 or not more than 20, is needed to obtain the desired effect of suppressing the skin effect and thereby reducing the resistance at high frequencies.

### II. EXAMPLE METHODS

A method according to the present disclosure for producing conductors 4 as described with reference to FIGS. 2 to 4 is illustrated in FIGS. 8 to 11. With reference to FIG. 8, a trench 10 is formed in the dielectric layer 5. The trench 10 has a depth and width in the order of 5 μm. The length of the trench is determined by the required layout of which the conductor 4 will be a part. The trench 10 may be formed by lithography and etching techniques. The trench has a level base 11 and upstanding sidewalls 12.

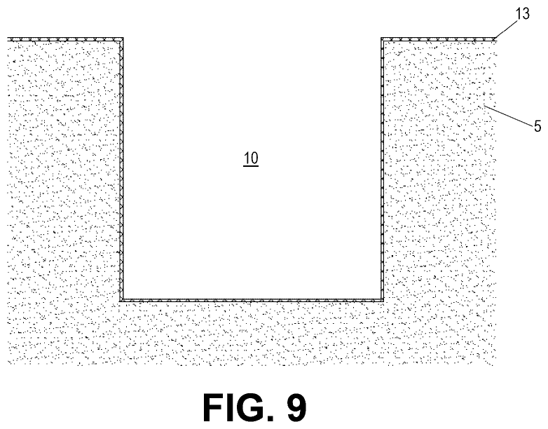

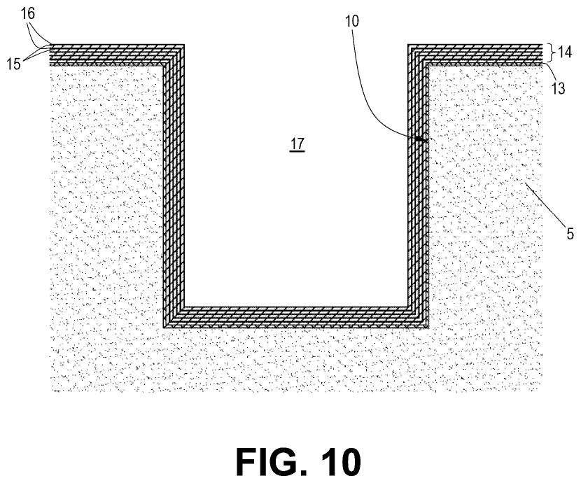

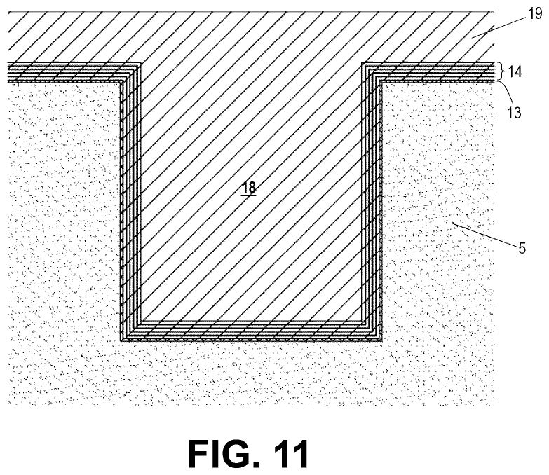

With reference to FIG. 9, the diffusion barrier layer 13 is deposited conformally on the dielectric layer 5, i.e. following the topography defined by the trench 10 and the upper surface 9 of the layer 5. Then, the Cu and Co layers 15 and 16 are deposited sequentially and alternately, also conformally following the topography, as illustrated in FIG. 10. Thus, the multistack 14 is formed, extending along the base 11 and on the sidewalls 12 of the trench 10 and on the upper surface of the dielectric layer 5, and thereby defining the second trench 17 inside the first trench 10 as described above.

Both the diffusion barrier 13 and the Cu and Co layers 15 and 16 may be formed by techniques such as PVD (physical vapour deposition) or ALD (atomic layer deposition). Cu is then deposited non-conformally, as illustrated in FIG. 11, i.e. the Cu fills the second trench 17, forming the bulk Cu portion 18 of the eventual conductor and a layer 19 of Cu on top of the horizontal parts of the multistack layer 14. The Cu 18,19 may be formed by first depositing a Cu seed layer conformally in the trench 17 and on the upper surface of the dielectric layer 5, followed by electrodeposition of Cu in the trench and on the upper surface.

Planarization is then applied, which may include grinding and CMP (chemical mechanical polishing), for removing the Cu layer 19 and the stack 14 from the upper surface of the dielectric layer 5. In some embodiments, a small upper portion of the dielectric layer 5 is removed, resulting in the embedded conductor 4 shown in FIG. 3, having an upper surface that is coplanar with the upper surface 9 of the dielectric layer 5.

These method steps correspond to a damascene-type processing for producing metaconductors aimed at reducing the skin effect at high frequencies, but differ in that the multistack layers formed on the sidewalls 12 of the trench 10 are not removed. The method is therefore less technically complex compared to methods wherein the sidewall-deposited portions of the multistack layers are removed. Embodiments where the thickness of the multistack 14 is small compared to the width W of the conductor are particularly advantageous, as it is clear that the sidewall-deposited portions do not have a detrimental effect on the resistance within a widely applicable frequency range, and that a limited number of layers suffices to obtain the desired skin effect suppression within the frequency range.

As stated above, this disclosure is applicable in a wide variety of technical configurations, not limited to the chiplet assembly shown in FIG. 1. Arrays of conductors 4 having similar dimensions can be applied in any assembly comprising any number of chips or chiplets mounted on an interposer. The conductors could be produced in a silicon bridge mounted on an interposer chip and aimed specifically at forming an electrically conductive bridge between adjacent chips or chiplets also mounted on the interposer. Also, conductors according to the invention can be applied internally in an integrated circuit chip, namely in the back end of line portion (BEOL) of the chip, for instance in the upper layers of the BEOL portion where conductors have larger dimensions compared to the lower layers.

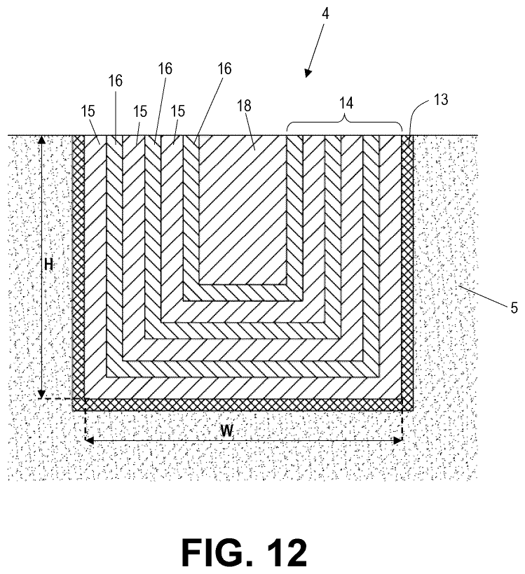

The disclosure is also not limited to conductors 4 having the multistack 14 confined to a thin outer layer as shown above. FIG. 12 shows a conductor 4 according to the invention, wherein the thickness of the multistack 14 is much higher compared to the width W of the conductor 4 as a whole. The width W and height H of the conductor 4 may, for example, be on the order of half a micrometre in this case, with the thickness of the barrier layer 13 and of the non-magnetic layers 15 (for example Cu) and the ferromagnetic layers 16 (for example Co) on the same order of magnitude as in the previously described embodiment, for example between 10 nm and 100 nm.

Applicable materials for the ferromagnetic and non-magnetic layers of the multistack 14 in a conductor according to the invention can include any non-magnetic metals with sufficient conductivity for practical signal processing applications, such as Cu, tungsten (W), aluminum (Al), etc. For the ferromagnetic layers, known ferromagnetic metals are applicable, including Co, iron (Fe), nickel (Ni), and any alloys of these and other materials.

In the examples described above, the first layer of the multistack 14, i.e. the layer formed directly on the base 11 and sidewalls 12 of the trench 10 or on the diffusion barrier layer 13, is a non-magnetic layer 15 (Cu in the described examples). In some embodiments, the first layer could be a ferromagnetic layer. The total number of layers in the multistack 14 may be an even number, in which case there are as many ferromagnetic layers as non-magnetic layers, or an uneven number, in which case the top layer of the stack is the same (ferromagnetic or non-magnetic) as the bottom layer. As in the presented example, the central conductive portion 18 may be non-magnetic and preferably formed of the same material as the non-magnetic layers of the multistack 14. It is also possible however that the central conductive portion 18 is formed of a ferromagnetic material, preferably the same ferromagnetic material as the ferromagnetic layers of the stack 14.

While the invention has been illustrated and described in detail in the drawings and foregoing description, such illustration and description are to be considered illustrative or exemplary and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

### III. ENUMERATED EXAMPLE EMBODIMENTS

Embodiments of the present disclosure may thus relate to one of the enumerated example embodiments (EEEs) listed below.
EEE 1 is a semiconductor component comprising a semiconductor substrate and at least one layer of dielectric material, said layer having a planar upper surface, wherein an electrical conductor is arranged in a first trench and formed in the layer of dielectric material, wherein the first trench comprises a base and a pair of upstanding sidewalls, and wherein the conductor comprises:
a stack of alternate ferromagnetic and non-magnetic layers, wherein the stack extends along the base and the sidewalls of the first trench so that the stack defines a second trench inside the first trench, and an electrically conductive portion that integrally fills the second trench.
EEE 2 is the semiconductor component according to EEE 1, wherein the electrically conductive portion that integrally fills the second trench is formed of a non-magnetic material.
EEE 3 is the semiconductor component according to EEE 1, wherein the
ferromagnetic layers of the stack are formed of the same ferromagnetic material and wherein the non-magnetic layers of the stack are formed of the same non-magnetic material, and wherein the electrically conductive portion that integrally fills the second trench is formed of the same material as the non-magnetic material of the non-magnetic layers of the stack.
EEE 4 is the semiconductor component according to EEE 1, wherein the thickness of the stack is less than 30% of the width of the conductor, as measured in a plane defined by the upper surface of the layer of dielectric material.
EEE 5 is the semiconductor component according to EEE 1, wherein the number of layers of the stack is not higher than 10.
EEE 6 is the semiconductor component according to EEE 1, wherein the width of the conductor as measured in a plane defined by the upper surface of the layer of dielectric material is at least one micrometer, and wherein the thickness of the layers of the stack is between 5 nm and 100 nm.
EEE 7 is the semiconductor component according to EEE 1, wherein the stack is in direct contact with a diffusion barrier layer that lines the base and the sidewalls of the first trench.
EEE 8 is the semiconductor component according to EEE 1, wherein the component is an interposer chip for mounting thereon a plurality of chiplets, and comprising at least one array of conductors arranged parallel to each other and configured to interconnect two chiplets.
EEE 9 is the semiconductor component according to EEE 1, wherein the component comprises a semiconductor chip comprising a back end of line portion including multiple levels of interconnected conductors, and wherein at least one of the conductors of the back end of line portion is a conductor as described in EEE 1.
EEE 10 is a semiconductor package comprising an interposer chip according to EEE 8 and a plurality of chiplets mounted on the interposer chip, and wherein the interposer chip comprises at least one array of said parallel conductors configured to interconnect two chiplets.
EEE 11 is a method for producing an electrical conductor comprising a stack of alternate ferromagnetic and non-magnetic layers, the method comprising:
providing a substrate comprising a layer of dielectric material having a planar upper surface,
producing a first trench in the layer of dielectric material, the first trench having a base and a pair of upstanding sidewalls,
producing a stack of said alternate ferromagnetic and non-magnetic layers along the base and the sidewalls of the first trench and on the upper surface of the layer of dielectric material, so that the stack defines a second trench inside the first trench,
producing a layer of electrically conductive material directly on a top layer of the stack, said layer filling the second trench, and
planarizing the stack and the layer of conductive material, thereby removing the stack from the upper surface of the layer of dielectric material.
EEE 12 is the method according to EEE 11, wherein the thickness of the stack is less than 30% of the width of the conductor, as measured in a plane defined by the upper surface of the layer of dielectric material.
EEE 13 is the method according to EEE 11, wherein the number of layers of the stack is not higher than 10.
EEE 14 is the method according to EEE 11, wherein the layer of electrically conductive material filling the second trench is a non-magnetic material.
EEE 15 is the method according to EEE 11, wherein the ferromagnetic layers of the stack are formed of the same ferromagnetic material and wherein the non-magnetic layers of the stack are formed of the same non-magnetic material, and wherein the electrically conductive portion that integrally fills the second trench is formed of the same material as the non-magnetic material of said the non-magnetic layers of the stack.
EEE 16 is the method according to EEE 11, wherein the stack is in direct contact with a diffusion barrier layer that lines the base and the sidewalls of the first trench.
EEE 17 is the method according to EEE 11, wherein the width of the conductor as measured in a plane defined by the upper surface of the layer of dielectric material is at least one micrometer, and wherein the thickness of the layers of the stack is between 5 nm and 100 nm.
EEE 18 is the method according to EEE 11, wherein the number of layers of the stack is an even number, and wherein the number of ferromagnetic layers equals the number of non-magnetic layers.
EEE 19 is the method according to EEE 11, wherein the number of layers of the stack is an odd number, and wherein the top layer of the stack is the same type of layer as a bottom layer of the stack.
EEE 20 is the method according to claim 11, wherein the conductor is produced within a silicon bridge mounted on an interposer chip.

### IV. CONCLUSION

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, operation, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step, block, or operation that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer-readable medium such as a storage device including RAM, a disk drive, a solid state drive, or another storage medium.

The computer-readable medium can also include non-transitory computer-readable media such as computer-readable media that store data for short periods of time like register memory and processor cache. The computer-readable media can further include non-transitory computer-readable media that store program code and/or data for longer periods of time. Thus, the computer-readable media may include secondary or persistent long term storage, like ROM, optical or magnetic disks, solid state drives, compact-disc read only memory (CD-ROM), for example. The computer-readable media can also be any other volatile or non-volatile storage systems. A computer-readable medium can be considered a computer-readable storage medium, for example, or a tangible storage device.

Moreover, a step, block, or operation that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A semiconductor component comprising a semiconductor substrate and at least one layer of dielectric material, said layer having a planar upper surface, wherein an electrical conductor is arranged in a first trench and formed in the layer of dielectric material, wherein the first trench comprises a base and a pair of upstanding sidewalls, and wherein the conductor comprises:
a stack of alternate ferromagnetic and non-magnetic layers, wherein the stack extends along the base and the sidewalls of the first trench so that the stack defines a second trench inside the first trench, and
an electrically conductive portion that integrally fills the second trench.

2. The semiconductor component according to claim 1, wherein the electrically conductive portion that integrally fills the second trench is formed of a non-magnetic material.

3. The semiconductor component according to claim 1, wherein the ferromagnetic layers of the stack are formed of the same ferromagnetic material and wherein the non-magnetic layers of the stack are formed of the same non-magnetic material, and wherein the electrically conductive portion that integrally fills the second trench is formed of the same material as the non-magnetic material of the non-magnetic layers of the stack.

4. The semiconductor component according to claim 1, wherein the thickness of the stack is less than 30% of the width of the conductor, as measured in a plane defined by the upper surface of the layer of dielectric material.

5. The semiconductor component according to claim 1, wherein the number of layers of the stack is not higher than 10.

6. The semiconductor component according to claim 1, wherein the width of the conductor as measured in a plane defined by the upper surface of the layer of dielectric material is at least one micrometer, and wherein the thickness of the layers of the stack is between 5 nm and 100 nm.

7. The semiconductor component according to claim 1, wherein the stack is in direct contact with a diffusion barrier layer that lines the base and the sidewalls of the first trench.

8. The semiconductor component according to claim 1, wherein the component is an interposer chip for mounting thereon a plurality of chiplets, and comprising at least one array of conductors arranged parallel to each other and configured to interconnect two chiplets.

9. The semiconductor component according to claim 1, wherein the component comprises a semiconductor chip comprising a back end of line portion including multiple levels of interconnected conductors, and wherein at least one of the conductors of the back end of line portion is a conductor as described in claim 1.

10. A semiconductor package comprising an interposer chip according to claim 8 and a plurality of chiplets mounted on the interposer chip, and wherein the interposer chip comprises at least one array of said parallel conductors configured to interconnect two chiplets.

11. A method for producing an electrical conductor comprising a stack of alternate ferromagnetic and non-magnetic layers, the method comprising:
providing a substrate comprising a layer of dielectric material having a planar upper surface,
producing a first trench in the layer of dielectric material, the first trench having a base and a pair of upstanding sidewalls,
producing a stack of said alternate ferromagnetic and non-magnetic layers along the base and the sidewalls of the first trench and on the upper surface of the layer of dielectric material, so that the stack defines a second trench inside the first trench,
producing a layer of electrically conductive material directly on a top layer of the stack, said layer filling the second trench, and
planarizing the stack and the layer of conductive material, thereby removing the stack from the upper surface of the layer of dielectric material.

12. The method according to claim 11, wherein the thickness of the stack is less than 30% of the width of the conductor, as measured in a plane defined by the upper surface of the layer of dielectric material.

13. The method according to claim 11, wherein the number of layers of the stack is not higher than 10.

14. The method according to claim 11, wherein the layer of electrically conductive material filling the second trench is a non-magnetic material.

15. The method according to claim 11, wherein the ferromagnetic layers of the stack are formed of the same ferromagnetic material and wherein the non-magnetic layers of the stack are formed of the same non-magnetic material, and wherein the electrically conductive portion that integrally fills the second trench is formed of the same material as the non-magnetic material of said the non-magnetic layers of the stack.

16. The method according to claim 11, wherein the stack is in direct contact with a diffusion barrier layer that lines the base and the sidewalls of the first trench.

17. The method according to claim 11, wherein the width of the conductor as measured in a plane defined by the upper surface of the layer of dielectric material is at least one micrometer, and wherein the thickness of the layers of the stack is between 5 nm and 100 nm.

18. The method according to claim 11, wherein the number of layers of the stack is an even number, and wherein the number of ferromagnetic layers equals the number of non-magnetic layers.

19. The method according to claim 11, wherein the number of layers of the stack is an odd number, and wherein the top layer of the stack is the same type of layer as a bottom layer of the stack.

20. The method according to claim 11, wherein the conductor is produced within a silicon bridge mounted on an interposer chip.
